(19) United States
(12) Patent Application Publication
(10) Pub. No.: US 2025/0386713 A1
(43) Pub. Date: Dec. 18, 2025

(54) DISPLAY PANEL AND DISPLAY DEVICE

(71) Applicant: HKC CORPORATION LIMITED, Shenzhen (CN)

(72) Inventors: HONGSONG WANG, Shenzhen (CN); Pei Xu, Shenzhen (CN)

(21) Appl. No.: 19/232,871

(22) Filed: Jun. 10, 2025

(30) Foreign Application Priority Data
Jun. 12, 2024 (CN) 202410752588.X

(51) Int. Cl. H10K 59/80

(52) U.S. Cl. CPC H10K 59/873

(57) ABSTRACT

A display panel and a display device are disclosed. The display panel includes: an encapsulation body, at an edge of which is formed a receiving cavity; multiple pixel modules disposed inside the encapsulation body, each being used for individual display; a moisture processing structure partially disposed inside the receiving cavity and forming a gap with the multiple pixel modules. The moisture processing structure includes: a housing, one part of which is connected to the encapsulation body, the other part is exposed outside the encapsulation body; a control device, disposed inside the housing on a side adjacent to the receiving cavity; and a power device, disposed inside the housing on a side facing away from the receiving cavity and configured to provide power to the control device to discharge the moisture from within the receiving cavity to the outside of the housing.

### CROSS-REFERENCE TO RELATED APPLICATIONS

This application claims the priority and benefit of Chinese patent application number 202410752588X, titled “Display Panel and Display Device” and filed Jun. 12, 2024 with China National Intellectual Property Administration, the entire contents of which are incorporated herein by reference.

### TECHNICAL FIELD

The present application relates to the display field, and more particularly to a display panel and a display device.

### BACKGROUND

The description provided in this section is intended for the mere purpose of providing background information related to the present application but does not necessarily constitute prior art.

In an OLED (Organic Light-Emitting Diode) display device, the light-emitting layer material and cathode material are sensitive to water and oxygen, and impurities in the environment may also affect the lifespan of the OLED display device.

In current OLED display panels, various organic or inorganic materials may be used to form an encapsulation body, which is used to seal the OLED display devices to prevent intrusion of external moisture. However, with prolonged encapsulation time, the sealing effect of the encapsulation body may diminish. When the external water and oxygen environment becomes complex, the risk of external moisture entering the display device increases, which affects the lifespan of the OLED display device.

Therefore, how to address the issue of water and oxygen intrusion inside the display panel and extend the lifespan of the display panel has become an urgent problem to be solved in this field.

### SUMMARY

Embodiments of the present application disclose a display panel and a display device, with the aim of resolving water and oxygen intrusion inside the display panel and extending the lifespan of the display panel.

Embodiments of the present application disclose a display panel, including an encapsulation body and a plurality of pixel modules. The plurality of pixel modules are arranged inside the encapsulation body. Each pixel module is used for individual display. A receiving cavity is formed at an edge of the encapsulation body. The display panel further includes a moisture processing structure that is partially disposed inside the receiving cavity, and there is defined a gap between the moisture processing structure and the plurality of pixel modules. The moisture processing structure includes a housing, a power device, and a control device. One part of the housing is connected to the encapsulation body, while the other part is exposed outside the encapsulation body. Both the power device and the control device are disposed inside the housing. The control device is disposed in the housing on a side adjacent to the receiving cavity. The power device is disposed in the housing on a side relatively far away from the receiving cavity. The power device is configured to supply power to the control device to control the control device to discharge the moisture from within the receiving cavity to the outside of the housing.

In some embodiments, the housing includes an air inlet, an air outlet, and an exhaust outlet. The housing further includes a first airflow channel and a second airflow channel. The first airflow channel is connected between the air inlet and the air outlet. The second airflow channel is connected between the control device and the exhaust outlet. The power device is disposed inside the first airflow channel. The airflow inside the first airflow channel is operative to provide power to the power device, which is configured to control the control device to switch between a first control state and a second control state. When the control device is in the second control state, the control device draws air from within the receiving cavity. When the control device is in the first control state, the control device discharges the moisture drawn from within the receiving cavity to the outside of the housing.

In some embodiments, the air outlet includes a first air outlet and a second air outlet. The first air outlet and the second air outlet are respectively disposed on opposite sides of the housing. The first airflow channel includes a main air cavity, a first branch airway, and a second branch airway. The first branch airway and the first air outlet are disposed on the same side. The second branch airway and the second air outlet are disposed on the same side. The side of the main air cavity relatively far away from the receiving cavity is connected to the air inlet. The side of the main air cavity relatively adjacent to the receiving cavity is connected to the first branch airway and the second branch airway. The end of the first branch airway facing away from the main air cavity is connected to the first air outlet. The end of the second branch airway facing away from the main air cavity is connected to the second air outlet. The power device is disposed inside the main air cavity. The power device divides the main air cavity into a first air duct and a second air duct. The airflow in the main air cavity is operative to drive the power device to switch between a first state and a second state. When the power device is in the first state, the first air duct communicates with the first branch airway and the second branch airway. The air pressure in the first branch airway controls the control device to be in the first control state. Alternatively, the second air duct communicates with the first branch airway and the second branch airway. The air pressure in the second branch airway controls the control device to be in the first control state. When the power device is in the second state, the first air duct, the second air duct, the first branch airway, and the second branch airway all communicate with each other, and the control device is in the second control state.

In some embodiments, the power device includes a fixing piece and a rotatable piece. The fixing piece is connected to an inner wall of the main air cavity. The rotatable piece is connected to the fixing piece via a rotating shaft. The rotatable piece is able to swing between the first air duct and the second air duct along the main air cavity. One side of the rotatable piece adjacent to the first air duct and the other side of the rotatable piece adjacent to the second air duct each have an arcuate shape. The rotatable piece also has the Coandă effect.

In some embodiments, the housing further includes a first cavity and a second cavity. The first cavity and the second cavity are disposed adjacent to each other. The second cavity is disposed adjacent to the receiving cavity. The first cavity is disposed on the side of the second cavity facing away from the receiving cavity. The control device includes a first control assembly and a switch assembly. The first control assembly is disposed within the first cavity. The switch assembly is disposed within the second cavity. The first cavity is connected to the exhaust outlet via the second airflow channel. An air suction tube is disposed within the second cavity, where one end of the air suction tube communicates with the first cavity and the other end communicates with the receiving cavity. When the control device is in the first control state, the first control assembly controls the second airflow channel to be opened thus communicating the exhaust outlet with the first cavity, while the switch assembly controls the air suction tube to be closed thus disconnecting the receiving cavity from the first cavity. When the control device is in the second control state, the first control assembly controls the second airflow channel to be closed thus disconnecting the exhaust outlet from the first cavity, while the switch assembly controls the air suction tube to be opened thus communicating the receiving cavity with the first cavity.

In some embodiments, the first cavity is disposed between the first branch airway and the second branch airway. One end of the first cavity is connected to the first branch airway, and the other end of the first cavity is connected to the second branch airway. The first cavity extends in a direction pointing from the first branch airway towards the second branch airway. The first control assembly includes a first control structure, a second control structure, and an elastic piece. The first control structure is disposed in the first cavity on a side adjacent to the first branch airway. The second control structure is disposed in the first cavity on a side adjacent to the second branch airway. The elastic piece is connected between the first control structure and the second control structure. In its natural state, the elastic piece extends the first control structure and the second control structure to the two ends of the first cavity, respectively. A connection port between the second airflow channel and the first cavity is disposed between the first control structure and the second control structure. When the first control structure is affected by an air pressure in the first branch airway, or the second control structure is affected by an air pressure in the second branch airway, the control device is in the first control state. When neither the first control structure nor the second control structure is affected by an air pressure, the control device is in the second control state.

In some embodiments, the first control structure includes a first support piece, a first support rod, and a first limiting member. The first support rod is connected between the first support piece and the first limiting member, extending the first limiting member into the first cavity. The second control structure includes a second support piece, a second support rod, and a second limiting member. The second support rod is connected between the second support piece and the second limiting member, extending the second limiting member into the first cavity. There is further disposed a first limiting piece and a second limiting piece on an inner wall of the first cavity. The first limiting piece is disposed between the first support piece and the second limiting member. The second limiting piece is disposed between the second support piece and the second limiting member. When the elastic piece is in its natural state, the side of the first limiting member adjacent to the first support piece abuts against the first limiting piece, and the side of the second limiting member adjacent to the second support piece abuts against the second limiting piece.

In some embodiments, the switch assembly includes a first assembly and a second assembly. The first assembly and the second assembly are disposed on opposite sides of the air suction tube along its direction of extension, respectively. The air suction tube is made of an elastic deformation material. The first assembly includes a first pipeline and a first pressing assembly. One end of the first pipeline is connected to the first cavity, and the other end of the first pipeline is connected to an inner wall of the second cavity facing away from the first cavity. The first pressing assembly includes a first connection piece and a first pressing piece. The first connection piece is disposed within the first pipeline. The first pressing piece is connected to the side of the first connection piece facing towards the air suction tube. There is further disposed a first control member in the first pipeline, the first control member being configured to control the first pressing piece to press or release the air suction tube. The second assembly includes a second pipeline and a second pressing assembly. One end of the second pipeline is connected to the first cavity, and the other end of the second pipeline is connected to the inner wall of the second cavity facing away from the first cavity. The second pressing assembly includes a second connection piece and a second pressing piece. The second connection piece is disposed within the second pipeline. The second pressing piece is connected to the side of the second connection piece facing towards the air suction tube. There is further disposed a second control member in the second pipeline, the second control member being configured to control the second pressing piece to press or release the air suction tube. When the control device is in the first control state, the first control member and the second control member respectively control the first pressing piece and the second pressing piece to compress the air suction tube, thus closing the air suction tube at the pressed portion. When the control device is in the second control state, the first control member and the second control member respectively control the first pressing piece and the second pressing piece to release the air suction tube. In some embodiments, the housing further includes a third cavity, which is disposed on the side of the second airflow channel adjacent to the exhaust outlet and is connected to the second airflow channel. The control device further includes a second control assembly, which is disposed within the third cavity. The second control assembly is used to control the communication and disconnection between the second airflow channel and the exhaust outlet. When the control device is in the first control state, the first control assembly controls the second control assembly to communicate the second airflow channel with the exhaust outlet. When the control device is in the second control state, the first control assembly controls the second control assembly to disconnect the second airflow channel from the exhaust outlet.

Embodiments of the present application further disclose a display device, which includes a rear shell. The display device further includes the aforementioned display panel, with the rear shell enclosing the display panel.

In this application, a moisture processing structure is disposed at an edge of the encapsulation body. The power device of the moisture processing structure supplies an operating power to the control device, thereby driving the control device to operate and continuously discharge the moisture from inside the receiving cavity to the outside of the display panel through the control device. That is, in this application, through the coordinated operation of the power device and the control device, the moisture inside the receiving cavity is actively drawn into the moisture processing structure and then discharged to the external environment through the moisture processing structure. Thus, even in a complex external water and oxygen environment, and even if some moisture enters the receiving cavity, the moisture that enters the encapsulation body can still be discharged through the cooperation of the power device and the control device, thereby ultimately achieving the goal of having no or very little water and oxygen inside the encapsulation body. This can effectively address the issue of water and oxygen intrusion inside the display panel and extend the lifespan of the display panel.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative efforts.

FIG. 1 is a schematic diagram of a first embodiment of a display panel of this application

FIG. 2 is a schematic diagram of a moisture processing structure in the first embodiment of the display panel of this application

FIG. 3 is a schematic diagram of a first control assembly in the first embodiment of the display panel of this application

FIG. 4 is a schematic diagram of a switch assembly in the first embodiment of the display panel of this application

FIG. 5 is a schematic diagram of a switch assembly in a second embodiment of a display panel of this application

FIG. 6 is a schematic diagram of one embodiment of a display device of this application.

In the drawings: 10, display device; 100, display panel; 300, rear shell; 110, encapsulation body; 111, receiving cavity; 120, pixel module; 130, moisture processing structure; 131, housing; 132, air inlet; 133, air outlet; 134, first air outlet; 135, second air outlet; 136, exhaust outlet; 140, first airflow channel; 141, main air cavity; 261, first air duct; 262, second air duct; 142, first branch airway; 143, second branch airway; 150, second airflow channel; 160, first cavity; 161, first limiting piece; 162, second limiting piece; 170, second cavity; 180, third cavity; 190, power device; 191, fixing piece; 192, rotatable piece; 193, rotating shaft; 200, control device; 210, first control assembly; 211, first control structure; 212, first support piece; 213, first support rod; 214, first limiting member; 215, second control structure; 216, second support piece; 217, second support rod; 218, second limiting member; 220, elastic piece; 230, second control assembly; 231, slidable piece; 232, spring; 240, switch assembly; 241, first assembly; 242, first pipeline; 243, first control member; 244, first pressing assembly; 245, first connection piece; 246, first pressing piece; 250, second assembly; 251, second pipeline; 252, second control member; 253, second pressing assembly; 254, second connection piece; 255, second pressing piece; 260, air suction tube; 270, buffer layer.

### DETAILED DESCRIPTION OF EMBODIMENTS

The present application will be described in detail below with reference to the accompanying drawings and some optional embodiments. It should be noted that, should no conflict be present, the embodiments or technical features described below can be arbitrarily combined to form new embodiments.

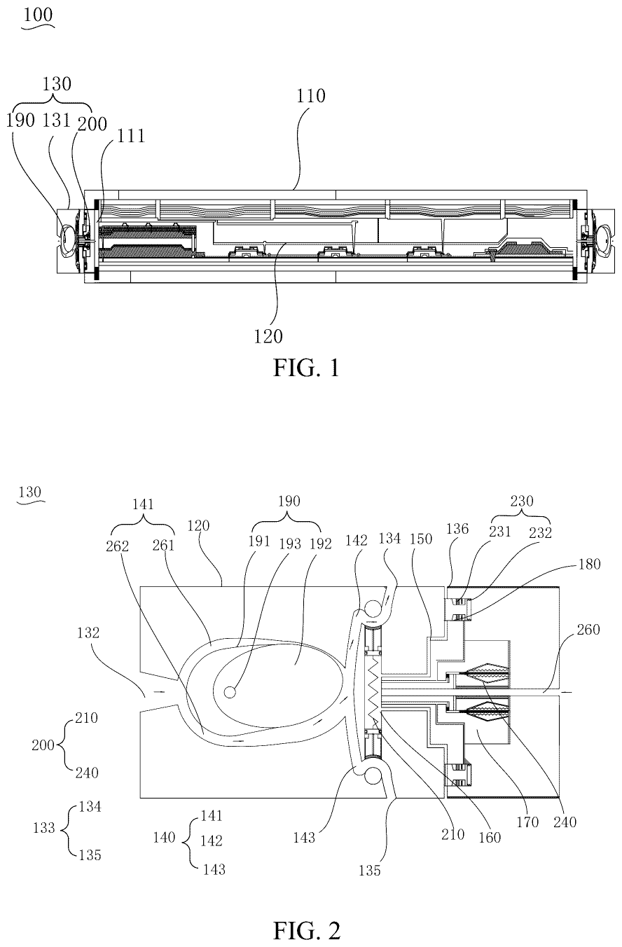

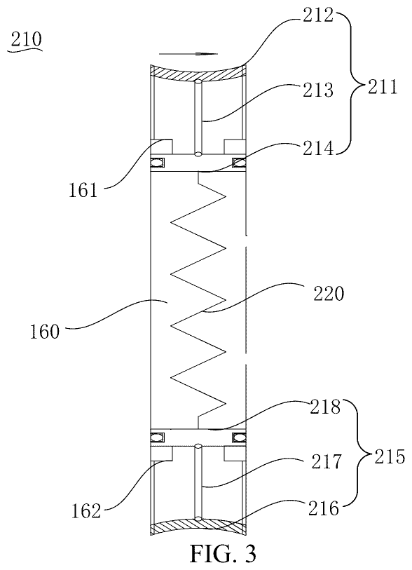

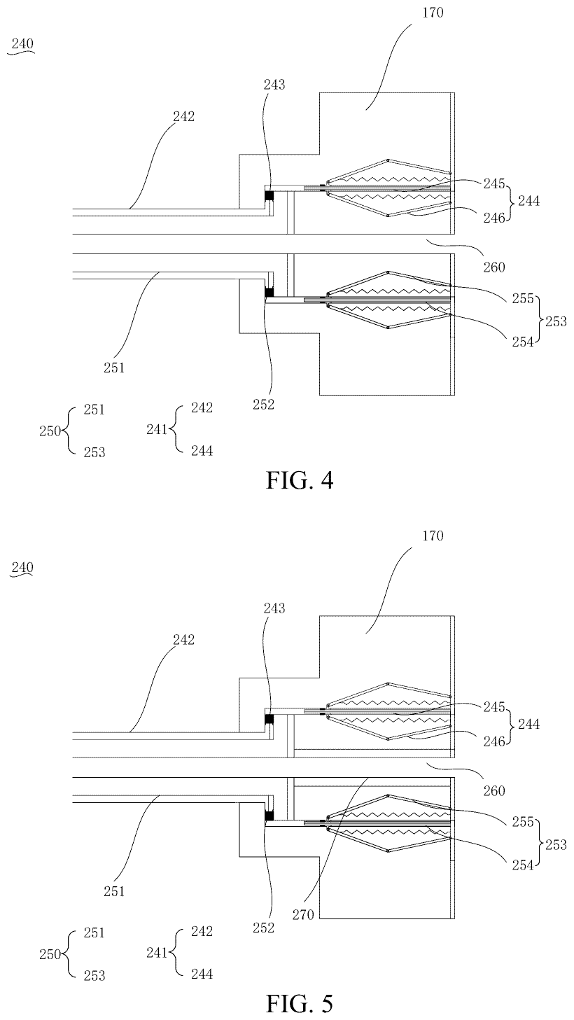

FIG. 1 is a schematic diagram of a first embodiment of a display panel of the present application. FIG. 2 is a schematic diagram of a moisture processing structure in the first embodiment of the display panel of the present application. FIG. 3 is a schematic diagram of a first control assembly in the first embodiment of the display panel of the present application. FIG. 4 is a schematic diagram of a switch assembly in the first embodiment of the display panel of the present application. As illustrated in FIGS. 1 to 4, embodiments of the present application disclose a display panel 100, including an encapsulation body 110 and a plurality of pixel modules 120. The plurality of pixel modules 120 are arranged within the encapsulation body 110. Each pixel module 120 is used for individual display. A receiving cavity 111 is formed at an edge of the encapsulation body 110. The display panel 100 further includes a moisture processing structure 130, which is partially disposed within the receiving cavity 111 and there is defined a gap between the water processing structure 130 and the plurality of pixel modules 120. The moisture processing structure 130 includes a housing 131, a power device 190, and a control device 200. A part of the housing 131 is connected to the encapsulation body 110. The other part of the housing 131 is exposed outside the encapsulation body 110. Both the power device 190 and the control device 200 are disposed within the housing 131. The control device 200 is disposed within the housing 131 on a side adjacent to the receiving cavity 111. The power device 190 is disposed within the housing 131 on a side relatively far away from the receiving cavity 111. The power device 190 is configured to provide power to the control device 200, so as to control the control device 200 to discharge the moisture from within the receiving cavity 111 to the outside of the housing 131.

In this application, a moisture processing structure 130 is disposed at an edge of the encapsulation body 110. The power device 190 of the moisture processing structure 130 supplies an operating power to the control device 200, thereby driving the control device 200 to operate and continuously discharge the moisture inside the receiving cavity 111 to the outside of the display panel 100 through the control device 200. That is, in this application, through the coordinated operation of the power device 190 and the control device 200, the moisture inside the receiving cavity 111 is actively drawn into the moisture processing structure 130 and then discharged to the external environment through the moisture processing structure 130. Thus, even in a complex external water and oxygen environment, and even if some moisture enters the receiving cavity 111, the moisture that enters the encapsulation body 110 can still be discharged through the cooperation of the power device 190 and the control device 200, thereby ultimately achieving the goal of having no or very little water and oxygen inside the encapsulation body 110. This can effectively address the issue of water and oxygen intrusion inside the display panel 100 and extend the lifespan of the display panel 100.

It is noteworthy that related display panels that solely rely on an encapsulation body may impose certain requirements on the usage environments. They may need to be used in relatively dry environments or environments with low humidity to prevent complex external water and oxygen environments from causing erosion inside the display panel.

Unlike related display panels that rely solely on the encapsulation body 110 for sealing, the display panel 100 in this application employs a power device 190 in conjunction with a control device 200 to actively extract and discharge moisture from within the display panel 100. Regardless of the complexity of the external water and oxygen environment, even if moisture or dust infiltrates the interior of the display panel 100, it will be actively extracted and discharged to the outside of the display panel 100. Thus, during use, the display panel 100 of this application can operate without concern for the impact of external water and oxygen environments on its interior, thereby overcoming limitations related to usage environments.

In particular, the housing 131 includes an air inlet 132, an air outlet 133, and an exhaust outlet 136. A first airflow channel 140 and a second airflow channel 150 are disposed inside the housing 131. The first airflow channel 140 is connected between the air inlet 132 and the air outlet 133. The second airflow channel 150 is connected between the control device 200 and the exhaust outlet 136. The power device 190 is arranged within the first airflow channel 140. The airflow inside the first airflow channel 140 provides power to the power device 190. The power device 190 controls the control device 200 to switch between a first control state and a second control state. When the control device 200 is in the second control state, the control device 200 draws air from within the receiving cavity 111. When the control device 200 is in the first control state, the control device 200 discharges the moisture drawn from within the receiving cavity 111 to the outside of the housing 131.

In this application, since a part of the housing 131 of the moisture processing structure 130 is disposed outside the encapsulation body 110 and is directly exposed to the external environment, external air can directly enter the interior of the housing 131 through the air inlet 132. When air enters the housing 131 through the air inlet 132, it first passes through the first airflow channel 140. The airflow generated in the first airflow channel 140 provides power to the power device 190, enabling the power device 190 to operate under the airflow and drive the control device 200 to switch between the first control state and the second control state.

It should be noted that the first control state of the control device 200 is a state in which the control device 200 discharges the moisture from within the receiving cavity 111, that is, the control device 200 expels the moisture inside the receiving cavity 111 to the outside of the housing 131. The second control state of the control device 200 is a state in which the control device 200 draws in the moisture from the receiving cavity 111, that is, the control device 200 draws the moisture inside the receiving cavity 111 into the housing 131 of the moisture processing structure 130.

Since the external air continuously flows, during the process in which the air continuously enters the housing 131 through the air inlet 132, there is always airflow passing through the first airflow channel 140. The airflow continuously provides power to the power device 190, and under the action of the airflow, the power device 190 repeatedly drives the control device 200 to switch between the first control state and the second control state, thereby enabling the control device 200 to continuously perform extraction and discharge of moisture inside the receiving cavity 111. Through the cooperation of the power device 190 and the control device 200, the moisture inside the receiving cavity 111 is extracted into the housing 131 and then discharged to the outside of the housing 131 through the second airflow channel 150, thereby ultimately achieving a state where there is no water and oxygen or an extremely low amount of water and oxygen inside the encapsulation body 110. This can effectively address the issue of water and oxygen intrusion inside the display panel 100 and extend the service life of the display panel 100.

Further, the air outlet 133 includes a first air outlet 134 and a second air outlet 135. The first air outlet 134 and the second air outlet 135 are respectively disposed on opposite sides of the housing 131. The first airflow channel 140 includes a main air cavity 141, a first branch airway 142, and a second branch airway 143. The first branch airway 142 and the first air outlet 134 are arranged on the same side. The second branch airway 143 and the second air outlet 135 are arranged on the same side. The side of the main air cavity 141 facing away from the receiving cavity 111 is connected to the air inlet 132. The side of the main air cavity 141 relatively adjacent to the receiving cavity 111 is connected to each of the first branch airway 142 and the second branch airway 143. One end of the first branch airway 142 facing away from the main air cavity 141 is connected to the first air outlet 134. One end of the second branch airway 143 facing away from the main air cavity 141 is connected to the second air outlet 135. The power device 190 is disposed inside the main air cavity 141 and divides the main air cavity 141 into a first air duct 261 and a second air duct 262. The airflow inside the main air cavity 141 drives the power device 190 to switch between a first state and a second state. When the power device 190 is in the first state, the first air duct 261 is in communication with the first branch airway 142 and the second branch airway 143, and the air pressure inside the first branch airway 142 controls the control device 200 to be in the first control state. Alternatively, the second air duct 262 is in communication with the first branch airway 142 and the second branch airway 143, and the air pressure inside the second branch airway 143 controls the control device 200 to be in the first control state. When the power device 190 is in the second state, the first air duct 261, the second air duct 262, the first branch airway 142, and the second branch airway 143 are all in communication with each other, and the control device 200 is in the second control state.

When the air from the external environment enters the first airflow channel 140 from the housing 131, it first enters the main air cavity 141, and the power device 190 disposed within the main air cavity 141 first comes into contact with the airflow. Under the action of the airflow, the power device 190 switches between the first state and the second state.

When the power device 190 is in the first state, the power device 190 communicates the first air duct 261 with the first branch airway 142 and the second branch airway 143. After the air from the external environment enters the housing 131 through the air inlet 132, the airflow passes through the first air duct 261, and then passes through the first branch airway 142 and the second branch airway 143. When the airflow is concentrated in the first branch airway 142, the air pressure inside the first branch airway 142 increases. Under the action of the air pressure, the control device 200 is in the first control state and discharges the moisture drawn from within the receiving cavity 111 inside the housing 131 to the outside of the housing 131.

Alternatively, the power device 190 communicates the second air duct 262 with the first branch airway 142 and the second branch airway 143. After the air from the external environment enters the housing 131 through the air inlet 132, the airflow passes through the second air duct 262, and then passes through the second branch airway 143 and the first branch airway 142. When the airflow is concentrated in the second branch airway 143, the air pressure inside the second branch airway 143 increases. Under the action of the air pressure, the control device 200 is in the first control state and discharges the moisture drawn from within the receiving cavity 111 inside the housing 131 to the outside of the housing 131.

When the power device 190 is in the second state, the power device 190 communicates the first air duct 261, the second air duct 262, the first branch airway 142, and the second branch airway 143 with each other, allowing smooth airflow throughout the housing 131 without being concentrated in any one channel. As a result, the control device 200 is not affected by the air pressure, so the control device 200 is in the second control state, drawing the moisture from the receiving cavity 111 into the interior of the housing 131.

In this application, external air continuously enters the housing 131, and the airflow within the main air cavity 141 drives the power device 190. The power device 190 continuously changes the opening or closing states of the various airflow channels within the housing 131, thereby causing pressure changes in the airflow channels adjacent to the control device 200. This allows the control device 200 to switch repeatedly between the first control state and the second control state under the effect of the air pressure. This enables the control device 200 to continuously extract and discharge moisture from within the receiving cavity 111, ultimately achieving a state where there is no moisture or very little moisture inside the encapsulation body 110. This can effectively address the issue of moisture intrusion inside the display panel 100 and extend the lifespan of the display panel 100.

In particular, the power device 190 includes a fixing piece 191 and a rotatable piece 192. The fixing piece 191 is connected to an inner wall of the main air cavity 141. The rotatable piece 192 is connected to the fixing piece 191 via a rotating shaft 193. The rotatable piece 192 is able to swing along the main air cavity 141 between the first air duct 261 and the second air duct 262. One side of the rotatable piece 192 adjacent to the first air duct 261 and the other side of the rotatable piece 192 adjacent to the second air duct 262 each have an arcuate shape. Furthermore, the rotatable piece 192 has the Coandă effect.

The rotatable piece 192 in this application is designed to have the Coandă effect. The Coandă effect, also known as the wall attachment effect, causes a fluid (water or air flow) to deviate from its original flow direction and instead follow the surface of a protruding object. When there is surface friction (or fluid viscosity) between the fluid and the surface of the object it flows over, as long as the curvature is not large, the fluid will flow along the surface of the object.

Based on the above principle, when the external air continuously enters the housing 131 through the air inlet 132, the airflow will flow along the side wall of the rotatable piece 192. When the airflow flows along the side wall of the rotatable piece 192 adjacent to the first air duct 261, under the effect of the airflow, the rotatable piece 192 will swing toward the second air duct 262 and eventually swing to the position of the second air duct 262. At this point, the rotatable piece 192 will block the second air duct 262, allowing the first air duct 261 to communicate with the first branch airway 142 and the second branch airway 143, while closing the communication of the second air duct 262 with both the first branch airway 142 and the second branch airway 143. A small portion of the airflow will flow along the side wall of the first air duct 261 adjacent to the rotatable piece 192 toward the first branch airway 142 located on the same side as the first air duct 261. The majority of the airflow will follow the curved side wall of the rotatable piece 192 and flow toward the second branch airway 143. At this point, the air pressure within the second branch airway 143 will increase, and under the effect of the air pressure, the control device 200 will be in the first control state, expelling the moisture drawn from within the receiving cavity 111 to the outside of the housing 131.

When the airflow flows along the side wall of the rotatable piece 192 adjacent to the second air duct 262, under the effect of the airflow, the rotatable piece 192 will swing toward the first air duct 261 and eventually swing to the position of the first air duct 261. At this point, the rotatable piece 192 will block the first air duct 261, allowing the second air duct 262 to communicate with the first branch airway 142 and the second branch airway 143, while closing off the communication of the first air duct 261 with both the first branch airways 142 and the second branch airway 143. A small portion of the airflow will flow along the side wall of the rotatable piece 192 adjacent to the second air duct 262 toward the second branch airway 143 located on the same side as the second air duct 262. The majority of the airflow will follow the curved side wall of the rotatable piece 192 and flow toward the first branch airway 142. At this point, the air pressure within the first branch airway 142 will increase, and under the effect of the air pressure, the control device 200 will be in the first control state, expelling the moisture drawn from within the receiving cavity 111 to the outside of the housing 131.

When the rotatable piece 192 swings to a position between the first air duct 261 and the second air duct 262 under the effect of the airflow, the rotatable piece 192 does not block the first air duct 261 and the second air duct 262. At this point, the first air duct 261, the second air duct 262, the first branch airway 142, and the second branch airway 143 are all interconnected. The airflow will circulate through the various air passages and then flow out from the first air outlet 134 and the second air outlet 135 to the outside of the housing 131. This way, there will be no air pressure generated on a side of the control device 200 at the first branch airway 142 or the second branch airway 143. At this point, the control device 200, not being affected by air pressure, is in the second control state and draws the moisture from within the receiving cavity 111 into the housing 131.

In this application, the rotatable piece 192, designed based on the Coandă effect, continuously swings within the main air cavity 141 under the continuous action of airflow. The changes in the swinging position of the rotatable piece 192 alter the opening or closing state of each airflow channel within the housing 131, causing air pressure changes in the first branch airway 142 or second branch airway 143 adjacent to the control device 200. This causes the control device 200 to repeatedly switch between the first and second control states under the influence of the air pressures, enabling it to continuously extract and expel moisture from within the receiving cavity 111, ultimately achieving a state in which the encapsulation body 110 contains little to no moisture or oxygen. This can effectively address the problem of moisture and oxygen intrusion inside the display panel 100 and extend the lifespan of the display panel 100.

Furthermore, the housing 131 further includes a first cavity 160 and a second cavity 170. The first cavity 160 and the second cavity 170 are disposed adjacent to each other. The second cavity 170 is disposed adjacent to the receiving cavity 111, while the first cavity 160 is disposed on the side of the second cavity 170 facing away from the receiving cavity 111. The control device 200 includes a first control assembly 210 and a switch assembly 240. The first control assembly 210 is disposed within the first cavity 160. The switch assembly 240 is disposed within the second cavity 170. A second airflow channel 150 is connected between the first cavity 160 and the exhaust outlet 136. An air suction tube 260 is disposed within the second cavity 170. One end of the air suction tube 260 communicates with the first cavity 160, and the other end of the air suction tube 260 communicates with the receiving cavity 111. When the control device 200 is in the first control state, the first control assembly 210 controls the second airflow channel 150 to be opened thus communicating the exhaust outlet 136 with the first cavity 160, while the switch assembly 240 closes the air suction tube 260 thus cutting off the communication between the receiving cavity 111 and the first cavity 160. When the control device 200 is in the second control state, the first control assembly 210 controls the second airflow channel 150 to be closed thus cutting off the communication between the exhaust outlet 136 and the first cavity 160, while the switch assembly 240 opens the air suction tube 260 thus communicating the receiving cavity 111 with the first cavity 160.

In this application, the air suction tube 260 is connected between the receiving cavity 111 and the first cavity 160, allowing moisture from within the receiving cavity 111 to enter the first cavity 160 via the air suction tube 260. The second airflow channel 150 is connected between the first cavity 160 and the exhaust outlet 136, thus allowing the receiving cavity 111 and the first cavity 160 to communicate with the exhaust outlet 136 via the air suction tube 260 and the second airflow channel 150. The moisture in the receiving cavity 111 can enter the first cavity 160 via the air suction tube 260, and then be discharged from the first cavity 160 through the second airflow channel 150 to the outside of the housing 131 via the exhaust outlet 136.

The first control assembly 210 is disposed inside the first cavity 160. The switch assembly 240 is disposed inside the second cavity 170. The first control assembly 210 controls the communication or disconnection among the first cavity 160, the second airflow channel 150, and the exhaust outlet 136 on one hand, and controls the switch assembly 240 to open or close the air suction tube 260 on the other hand.

When the control device 200 is in the second control state, the first control assembly 210 controls the second airflow channel 150 to be closed so as to cut off the communication of the exhaust outlet 136 with the first cavity 160, while the switch assembly 240 controls the air suction tube 260 to be opened so as to communicate the receiving cavity 111 with the first cavity 160. At this point, the first cavity 160 is isolated from the exhaust outlet 136, and the air suction tube 260 communicates the first cavity 160 with the receiving cavity 111, allowing the moisture from the receiving cavity 111 to enter the first cavity 160 through the air suction tube 260.

When the control device 200 is in the first control state, the first control assembly 210 controls the second airflow channel 150, the exhaust outlet 136, and the first cavity 160 to communicate with each other, while the switch assembly 240 controls the air suction tube 260 to be closed to cut off the communication between the receiving cavity 111 and the first cavity 160. At this point, the receiving cavity 111 is isolated from the first cavity 160, and the moisture in the receiving cavity 111 no longer enters the first cavity 160. The moisture drawn by the first cavity 160 from the receiving cavity 111 is discharged through the second airflow channel 150 from the exhaust outlet 136 to the outside of the housing 131.

Through the above process, the control device 200, driven by the power device 190, repeatedly switches between the first and second control states, thereby causing the moisture processing structure 130 to continuously extract and expel the moisture inside the encapsulation body 110, ultimately achieving a state in which the encapsulation body 110 contains little or no water and oxygen. This can effectively address the issue of water and oxygen intrusion inside the display panel 100, thereby extending the lifespan of the display panel 100.

Furthermore, the first cavity 160 is disposed between the first branch airway 142 and the second branch airway 143. One end of the first cavity 160 is connected to the first branch airway 142, and the other end is connected to the second branch airway 143. The first cavity 160 extends in the direction pointing from the first branch airway 142 towards the second branch airway 143. The first control structure 211 is disposed in the first cavity 160 on a side adjacent to the first branch airway 142. The second control structure 215 is disposed in the first cavity 160 on a side adjacent to the second branch airway 143. The elastic piece 220 is connected between the first control structure 211 and the second control structure 215. In its natural state, the elastic piece 220 extends the first control structure 211 and the second control structure 215 to the two ends of the first cavity 160, respectively. A connection port between the second airflow channel 150 and the first cavity 160 is disposed between the first control structure 211 and the second control structure 215. When the first control structure 211 is affected by an air pressure in the first branch airway 142, or when the second control structure 215 is affected by an air pressure in the second branch airway 143, the control device 200 is in the first control state. When neither the first control structure 211 nor the second control structure 215 is affected by air pressure, the control device 200 is in the second control state.

The elastic piece 220 can be implemented as a spring 232, so that both ends of the spring 232 may be connected to the first control structure 211 and the second control structure 215, respectively. When the spring 232 is in its natural state, it extends the first control structure 211 to the end of the first cavity 160 adjacent to the first branch airway 142, and extends the second control structure 215 to the end of the first cavity 160 adjacent to the second branch airway 143.

Since the first cavity 160 is disposed between the first branch airway 142 and the second branch airway 143, the air pressure generated by either the first branch airway 142 or the second branch airway 143 will first act on the first control assembly 210 disposed within the first cavity 160. When the air pressure in the first branch airway 142 increases, the air pressure in the first branch airway 142 will act on the first control structure 211, causing the first control structure 211 to move toward the second control structure 215 within the first cavity 160 and compress the elastic piece 220. As the first control structure 211 moves, it compresses the space within the first cavity 160, reducing the volume of the first cavity 160 and causing the air pressure within the first cavity 160 to increase. At this point, the control device 200 is in the first control state. The first control assembly 210 controls the first cavity 160 to communicate with the second airflow channel 150 and the exhaust outlet 136, while also controlling the switch assembly 240 to close the air suction tube 260 thus cutting off the communication between the receiving cavity 111 and the first cavity 160, and expelling the moisture inside the housing 131 to the outside of the housing 131.

Similarly, when the air pressure in the second branch airway 143 increases, the air pressure in the second branch airway 143 will act on the second control structure 215, causing the second control structure 215 to move toward the first control structure 211 within the first cavity 160 and compress the elastic piece 220. As the second control structure 215 moves, it compresses the space within the first cavity 160, reducing the volume of the first cavity 160 and causing the air pressure within the first cavity 160 to increase, thus placing the control device 200 in the first control state and expelling the moisture inside the housing 131 to the outside of the housing 131.

In particular, the first control structure 211 includes a first support piece 212, a first support rod 213, and a first limiting member 214. The first support rod 213 is connected between the first support piece 212 and the first limiting member 214, extending the first limiting member 214 into the first cavity 160. The second control structure 215 includes a second support piece 216, a second support rod 217, and a second limiting member 218. The second support rod 217 is connected between the second support piece 216 and the second limiting member 218, extending the second limiting member 218 into the first cavity 160. A first limiting piece 161 and a second limiting piece 162 are further disposed on an inner wall of the first cavity 160. The first limiting piece 161 is disposed between the first support piece 212 and the first limiting member 214. The second limiting piece 162 is disposed between the second support piece 216 and the second limiting member 218. When the elastic piece 220 is in a natural state, the side of the first limiting member 214 adjacent to the first support piece 212 abuts against the first limiting piece 161, and the side of the second limiting member 218 adjacent to the second support piece 216 abuts against the second limiting piece 162.

When neither the first control structure 211 nor the second control structure 215 is subjected to an air pressure, the elastic piece 220 connected to the first control structure 211 and the second control structure 215 is in a natural state. On one hand, the first limiting piece 161 and the second limiting piece 162 prevent the first control structure 211 and the second control structure 215 from falling out of the first cavity 160 under the limiting action of the first limiting piece 161 and the second limiting piece 162, allowing movement only within the first cavity 160, thereby ensuring the operational stability of the first control assembly 210. On the other hand, when neither the first control structure 211 nor the second control structure 215 is subjected to an air pressure, the elastic restoring force of the elastic piece 220 enables the first control structure 211 and the second control structure 215 to return to their respective designated positions, facilitating a gradual increase in the volume of the first cavity 160 during the return process of the first control structure 211 or the second control structure 215, thereby gradually reducing the air pressure inside the first cavity 160, and enhancing the thoroughness of drawing the moisture from within the receiving cavity 111 into the first cavity 160 under a negative pressure.

Furthermore, when the first control structure 211 moves toward the second control structure 215 within the first cavity 160 under the action of air pressure, the first limiting member 214 of the first control structure 211 compresses the elastic piece 220. The force generated by the deformation of the elastic piece 220 acts on the second control structure 215. At this time, the side of the second limiting member 218 of the second control structure 215 adjacent to the second support piece 216 abuts against the second limiting piece 162, so that the overall position of the second control structure 215 is restricted by the second limiting piece 162, thereby keeping the second control structure 215 stationary. As the first control structure 211 moves toward the second control structure 215, the space inside the first cavity 160 is compressed from the side of the first branch airway 142 toward the side of the second branch airway 143, thereby increasing the air pressure inside the first cavity 160 and placing the control device 200 in the first control state.

Similarly, when the second control structure 215 moves toward the first control structure 211 within the first cavity 160 under the action of air pressure, the second limiting member 218 of the second control structure 215 compresses the elastic piece 220. The force generated by the deformation of the elastic piece 220 acts on the first control structure 211. At this time, the side of the first limiting member 214 of the first control structure 211 adjacent to the first support piece 212 abuts against the first limiting piece 161, so that the overall position of the first control structure 211 is restricted by the first limiting piece 161, thereby keeping the first control structure 211 stationary. As the second control structure 215 moves toward the first control structure 211, the space inside the first cavity 160 is compressed from the side of the second branch airway 143 toward the side of the first branch airway 142, thereby increasing the air pressure inside the first cavity 160 and placing the control device 200 in the first control state.

In this application, the displacement generated when the first control structure 211 or the second control structure 215 is subjected to air pressure compresses the volume of the first cavity 160, thereby increasing the air pressure inside the first cavity 160, placing the first cavity 160 in a high-pressure state. Through the airflow generated under the high-pressure state, the switch assembly 240 is controlled to close the air suction tube 260 while the second airflow channel 150 and the exhaust outlet 136 are opened, thereby discharging the moisture inside the housing 131 to the outside of the housing 131. During the restoring process of the first control structure 211 or the second control structure 215, the volume of the first cavity 160 is increased, thereby lowering the air pressure inside the first cavity 160 and placing the first cavity 160 in a low-pressure state. Under the negative pressure action of the low-pressure first cavity 160, the switch assembly 240 is controlled to open the air suction tube 260 while the second airflow channel 150 and the exhaust outlet 136 are closed, so that the moisture inside the receiving cavity 111 enters the first cavity 160, thereby achieving the suction of moisture from inside the display panel 100 into the moisture processing structure 130, completing the suction operation. Through repeated extraction and discharge processes, a state where there is no water and oxygen or very little water and oxygen inside the encapsulation body 110 is eventually achieved, which can effectively address the problem of water and oxygen intrusion inside the display panel 100 and extend the service life of the display panel 100.

Further, the switch assembly 240 includes a first assembly 241 and a second assembly 250. The first assembly 241 and the second assembly 250 are respectively disposed on both sides in the extending direction of the air suction tube 260. The air suction tube 260 is made of an elastic deformation material. The first assembly 241 includes a first pipeline 242 and a first pressing assembly 244. One end of the first pipeline 242 communicates with the first cavity 160, and the other end of the first pipeline 242 is connected to an inner wall of the second cavity 170 facing away from the first cavity 160. The first pressing assembly 244 includes a first connection piece 245 and a first pressing piece 246. The first connection piece 245 is disposed inside the first pipeline 242. The first pressing piece 246 is connected to the side of the first connection piece 245 facing toward the air suction tube 260. A first control member 243 is further disposed inside the first pipeline 242, and the first control member 243 is configured to control the first pressing piece 246 to press or release the air suction tube 260. The second assembly 250 includes a second pipeline 251 and a second pressing assembly 253. One end of the second pipeline 251 communicates with the first cavity 160, and the other end of the second pipeline 251 is connected to the inner wall of the second cavity 170 facing away from the first cavity 160. The second pressing assembly 253 includes a second connection piece 254 and a second pressing piece 255. The second connection piece 254 is disposed inside the second pipeline 251. The second pressing piece 255 is connected to the side of the second connection piece 254 facing toward the air suction tube 260. A second control member 252 is further disposed inside the second pipeline 251, and the second control member 252 is configured to control the second pressing piece 255 to press or release the air suction tube 260. When the control device 200 is in the first control state, the first control member 243 and the second control member 252 respectively control the first pressing piece 246 and the second pressing piece 255 to compress the air suction tube 260, thereby closing the air suction tube 260 at the pressed portion. When the control device 200 is in the second control state, the first control member 243 and the second control member 252 respectively control the first pressing piece 246 and the second pressing piece 255 to release the air suction tube 260.

In the present application, when the control device 200 is in the first control state, the first control assembly 210 compresses the volume of the first cavity 160, so that the first cavity 160 is in a high-pressure state. The airflow passes through the first pipeline 242 and the second pipeline 251 to generate an air pressure. Under the action of the air pressure, the first control member 243 and the second control member 252 respectively control the first pressing piece 246 and the second pressing piece 255 to compress the air suction tube 260, thereby closing the air suction tube 260 at the pressed portion and isolating the receiving cavity 111 from the first cavity 160. Thus, the moisture inside the housing 131 can only be discharged through the second airflow channel 150 and the exhaust outlet 136, thereby completing the exhausting operation.

When the control device 200 is in the second control state, the first control assembly 210 releases the volume of the first cavity 160, so that the first cavity 160 is in a low-pressure state. Under the effect of negative pressure, the gas in the first pipeline 242 and the second pipeline 251 is drawn into the first cavity 160. At this time, the first control member 243 and the second control member 252 respectively control the first pressing piece 246 and the second pressing piece 255 to release the air suction tube 260, thereby opening the air suction tube 260 at the pressed portion and enabling communication between the receiving cavity 111 and the first cavity 160. Under the effect of negative pressure, the moisture inside the receiving cavity 111 enters the first cavity 160 through the air suction tube 260, thereby completing the suction operation.

In this application, when the air pressure inside the first cavity 160 changes between high pressure and low pressure, the generated airflow respectively acts on the first control member 243 and the second control member 252, thereby controlling the first pressing assembly 244 and the second pressing assembly 253 via the first control member 243 and the second control member 252, so that the first pressing assembly 244 and the second pressing assembly 253 open or close the air suction tube 260, thereby enabling or cutting off the communication between the first cavity 160 and the receiving cavity 111.

In particular, the first control member 243 and the second control member 252 may each be a first magnet. A second magnet may be disposed at a position of each of the first connection piece 245 and the second connection piece 254 corresponding to the respective first magnet. The magnetic polarities of the opposing ends of the first magnet and the second magnet that correspond to each other are opposite. Furthermore, the first pipeline 242 and the second pipeline 251 are each a pipeline structure having a height difference. Each first magnet is connected at the height difference junction of the first pipeline 242 or the second pipeline 251 via a spring 232. When the spring 232 is in its natural state, the first magnet does not correspond to the position of the respective second magnet. The first pressing piece 246 and the second pressing piece 255 may each be composed of two rotating rods connected at their ends, and a spring 232 is further connected between the two rotating rods. The first connection piece 245 and the second connection piece 254 may each be a retractable sleeve structure. The two ends of the first pressing piece 246 may be fixed to the sleeve of the first connection piece 245, and the two ends of the second connection piece 254 may be fixed to the sleeve of the second connection piece 254. When the first connection piece 245 and the second connection piece 254 stretch or contract, they drive the first pressing piece 246 and the second pressing piece 255 to stretch or retract.

When the control device 200 is in the first control state, the first control assembly 210 compresses the volume of the first cavity 160, causing the first cavity 160 to be in a high-pressure state. The airflow generates air pressure within the first pipeline 242 and the second pipeline 251. Under the influence of the air pressure, each first magnet is pushed to the position corresponding to the respective second magnet. Since the magnetic poles of the opposing ends of the first and second magnets are opposite, the first connection piece 245 and the second connection piece 254 will contract. During the contraction process, the first pressing piece 246 and the second pressing piece 255 will also contract. The two rotating rods of the first pressing piece 246 and the second pressing piece 255 will contract, squeezing the spring 232 between the two rods. The ends of the first pressing piece 246 and the second pressing piece 255 will gradually approach the air suction tube 260 and press against it, thereby shutting off the air suction tube at the portion compressed by the first pressing piece 246 and second pressing piece 255. At this point, the first cavity 160 and the receiving cavity 111 are isolated from each other, and the moisture inside the housing 131 can only be discharged to the outside of the housing 131 through the second airflow channel 150 via the exhaust outlet 136, thus completing the discharge process.

When the control device 200 is in the second control state, the first control assembly 210 releases the air pressure in the first cavity 160, thereby increasing the volume of the first cavity 160 and causing the first cavity 160 to be in a low-pressure state. In the negative pressure state, the airflow in the first pipeline 242 and the second pipeline 251 will be drawn back into the first cavity 160. The first magnet returns to its initial position under the restoring force of the spring 232, causing the first magnet and the second magnet to misalign. Under the restoring force of the spring 232 between the two rods of the first pressing piece 246 and the spring 232 between the two rods of the second pressing piece 255, the first pressing piece 246 and the second pressing piece 255 respectively push apart the first connection piece 245 and the second connection piece 254. This causes the ends of the first pressing piece 246 and the second pressing piece 255 to release the air suction tube 260 and gradually move away from it, thereby opening the air suction tube at the portion compressed by the first pressing piece 246 and second pressing piece 255. At this point, the first cavity 160 and the receiving cavity 111 are in communication with each other, and the moisture in the receiving cavity 111 enters the first cavity 160 through the air suction tube 260, thereby completing the extraction process.

The housing 131 further includes a third cavity 180, which is disposed on the side of the second airflow channel 150 adjacent to the exhaust outlet 136 and is connected to the second airflow channel 150. The control device 200 further includes a second control assembly 230, which is disposed within the third cavity 180. The second control assembly 230 is configured to control the communication and disconnection between the second airflow channel 150 and the exhaust outlet 136. When the control device 200 is in the first control state, the first control assembly 210 controls the second control assembly 230 to communicate the second airflow channel 150 with the exhaust outlet 136. When the control device 200 is in the second control state, the first control assembly 210 controls the second control assembly 230 to disconnect the second airflow channel 150 from the exhaust outlet 136.

The second control assembly 230 includes a slidable piece 231 and a spring 232. One end of the spring 232 is connected to the slidable piece 231, and the other end is connected to the sidewall of the third cavity 180 facing away from the second airflow channel 150. The slidable piece 231 can move along the direction of extension of the third cavity 180. When the spring 232 is in its natural state, it extends the slidable piece 231 to the position of the second airflow channel 150. At this point, the slidable piece 231 closes the second airflow channel 150 from the exhaust outlet 136.

When the control device 200 is in the first control state, the air pressure inside the first cavity 160 increases. The airflow inside the first cavity 160 rushes into the second airflow channel 150, causing the air pressure inside the second airflow channel 150 to increase accordingly, thereby pushing the slidable piece 231 under the action of air pressure. The slidable piece 231 compresses the spring 232 and moves toward the side of the third cavity 180 facing away from the second airflow channel 150, thereby gradually enabling the communication between the second airflow channel 150 and the exhaust outlet 136. Eventually, the second airflow channel 150 and the exhaust outlet 136 are fully opened, allowing the moisture inside the housing 131 to be discharged to the outside of the housing 131 through the second airflow channel 150 and the exhaust outlet 136, thereby completing the exhaust operation.

When the control device 200 is in the second control state, the air pressure inside the first cavity 160 decreases. Under the action of negative pressure, air is drawn from within the inside of the housing 131. At this time, the air pressure inside the second airflow channel 150 also decreases accordingly. The slidable piece 231 moves back to the position of the second airflow channel 150 under the action of the spring 232, thereby shutting off the communication between the second airflow channel 150 and the exhaust outlet 136. In this way, the first cavity 160 can absorb only the moisture inside the receiving cavity 111 through the air suction tube 260, without being affected by external moisture.

In this application, a power device 190 utilizing the Coandă effect is adopted to provide a pulsed force for the control device 200. During the interval period, the elastic piece 220 returns to its original state, increasing the volume inside the first cavity 160, thereby causing the first cavity 160 to be in a low-pressure state. At this time, the second control assembly 230 cannot be opened, the first assembly 241 and the second assembly 250 are in an open state, external gas cannot enter the first cavity 160, and the moisture inside the receiving cavity 111 is drawn into the first cavity 160, which is the moisture intake phase. At this moment, the Coandă pulsed force reaches its peak, and the first control structure 211 or the second control structure 215 is subjected to the action of air pressure. At this time, the volume inside the first cavity 160 is compressed, resulting in a high-pressure state. The first magnets respectively apply control forces to the first assembly 241 and the second assembly 250 within the first pipeline 242 and the second pipeline 251, prompting the first assembly 241 and the second assembly 250 to expand. At this time, the first assembly 241 and the second assembly 250 close the air suction tube 260. At this moment, under the action of high pressure, the second airflow channel 150 opens the second control assembly 230, allowing the moisture inside the first cavity 160 to be discharged outside the housing 131.

In addition, when it is needed to mount the moisture processing structure 130 onto the encapsulation body 110, the housing 131 of the moisture processing structure 130 may be fixed to the encapsulation body 110 by means of screwing, or alternatively by using adhesive bonding. This application does not impose specific limitations on the fixing method between the moisture processing structure 130 and the encapsulation body 110, and the screwing fixation or adhesive fixation is merely provided herein as an example.

It is noteworthy that the fixation between the moisture processing structure 130 and the encapsulation body 110 in this application does not require excessively stringent requirements regarding sealing or airtightness. Even if installation errors or process deviations cause installation gaps, it will not significantly affect the normal operation of the moisture processing structure 130, and it can still ensure that even if some moisture from the external environment enters the receiving cavity 111 through the gaps, it will be actively drawn into the housing 131 by the moisture processing structure 130 and then discharged to the external environment. This not only facilitates assembly but also improves the installation tolerance, contributing to extending the service life of the display panel 100.

FIG. 5 is a schematic view of a switch assembly in a second embodiment of a display panel according to the present application. As shown in FIG. 5, the embodiment illustrated in FIG. 5 is an improvement based on FIG. 4, where a buffer layer 270 is further disposed on the side of the air suction tube 260 facing toward the first pressing piece 246 and the second pressing piece 255.

The present embodiment differs from the previous embodiment in that, in this embodiment, a buffer layer 270 is disposed on the air suction tube 260. The buffer layer 270 can be made of elastic foam, sponge, or other materials, and is attached to both sides of the air suction tube 260. Alternatively, the buffer layer 270 may be a sleeve structure that fits the shape of the air suction tube 260, and is sleeved onto the air suction tube 260.

When the first pressing piece 246 and second pressing piece 255 press against the air suction tube 260, the buffer layer 270 buffers the forces exerted by the first pressing piece 246 and second pressing piece 255. This can effectively address the issue of the air suction tube 260 being damaged due to repeated pressing by the first pressing piece 246 and second pressing piece 255, effectively extending the service life of the air suction tube 260, and further extending the service life of the moisture processing structure 130 and the display panel 100 (as illustrated in FIG. 1).

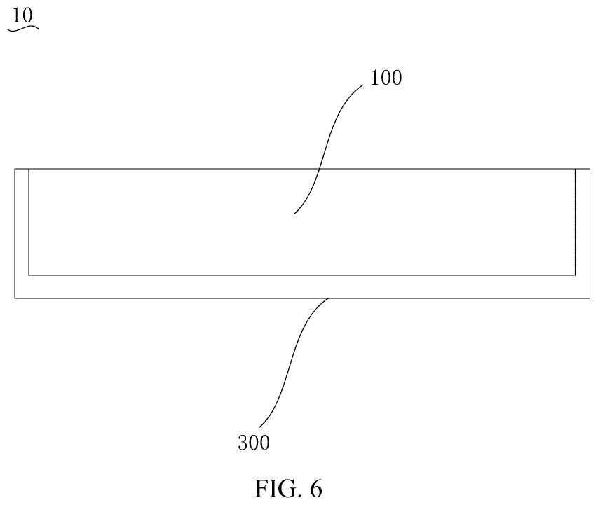

FIG. 6 is a schematic diagram of an embodiment of a display device in the present application. As shown in FIG. 6, embodiments of the present application further disclose a display device 10, which includes a rear shell 300. The display device 10 further includes the aforementioned display panel 100, and the rear shell 300 encloses the display panel 100. The rear shell 300 is used to protect the display panel 100 from damage caused by external forces and can also prevent dust and moisture from entering the interior of the display device 10 to some extent, which helps extend the lifespan of the display device 10.

It should be noted that this application primarily targets a display device 10 with an OLED display panel 100, but it can also be a display device 10 with other types of display panels 100. This application does not impose specific limitations on the type of display panel 100 in the display device 10.

Furthermore, again with reference to the previous FIGS. 1 to 5, the display device 10 in this application is primarily intended for use in environments with complex external flow fields, such as automotive rear-view mirrors. The display device 10 in this application may be used in environments with relatively abundant water and oxygen, without the need to consider external water and oxygen conditions. In related display devices 10, the display panel 100 may be encapsulated with an encapsulation body 110 made of organic or inorganic materials. As usage time increases, the sealing effectiveness of the encapsulation body 110 decreases, allowing external moisture to easily enter the interior of the display panel 100, which in turn affects the lifespan of the display device 10.

Based on the above problem, the present application improves the display panel 100 in the display device 10. The present application sets a moisture processing structure 130 at the edge of the encapsulation body 110 and uses the power device 190 in the moisture processing structure 130 to provide an operating power for the control device 200, thereby driving the control device 200 to operate. The control device 200 continuously discharges the moisture from the receiving cavity 111 to the outside of the display panel 100. In other words, under the coordinated operation of the power device 190 and control device 200, the moisture inside the receiving cavity 111 is actively drawn in and discharged, first drawing the moisture from the receiving cavity 111 into the moisture processing structure 130 and then discharging it to the external environment through the moisture processing structure 130. Thus, even in a complex external water and oxygen environment, if some moisture enters the receiving cavity 111, the coordination between the power device 190 and the control device 200 will remove the moisture that enters the interior of the encapsulation body 110, ultimately achieving a state where the encapsulation body 110 has little or no moisture or water oxygen. This can effectively address the issue of water and oxygen intrusion inside the display panel 100, extend the lifespan of the display panel 100 and the display device 10, and further enhance the quality of the display device 10.

It should be noted that the inventive concept of the present application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling in the scope of protection of the present application.

What is claimed is:

1. A display panel, comprising an encapsulation body and a plurality of pixel modules disposed inside the encapsulation body; wherein each of the plurality of pixel modules is configured for individual display, and wherein there is disposed a receiving cavity at an edge of the encapsulation body;
wherein the display panel further comprises a moisture processing structure, which is partially disposed inside the receiving cavity, and there is defined a gap between the moisture processing structure and the plurality of pixel modules;
wherein the moisture processing structure comprises a housing, a power device, and a control device; wherein one part of the housing is connected to the encapsulation body, and wherein another part of the housing is exposed outside the encapsulation body; wherein both the power device and the control device are disposed within the housing, wherein the control device is disposed in the housing on a side adjacent to the receiving cavity, and wherein the power device is disposed in the housing on a side facing away from the receiving cavity;
wherein the power device is configured to supply power to the control device to control the control device to discharge moisture from within the receiving cavity to an outside of the housing.

2. The display panel as recited in claim 1, wherein the housing comprises an air inlet, an air outlet, and an exhaust outlet; wherein the housing further comprises a first airflow channel and a second airflow channel, wherein the first airflow channel is connected between the air inlet and the air outlet, and wherein the second airflow channel is connected between the control device and the exhaust outlet;
wherein the power device is disposed within the first airflow channel, wherein an airflow within the first airflow channel is operative to supply power to the power device, and wherein the power device is configured to control the control device to switch between a first control state and a second control state.

3. The display panel as recited in claim 2, wherein when the control device is in the second control state, the control device is configured to perform a suction operation from within the receiving cavity, and wherein when the control device is in the first control state, the control device is configured to discharge the moisture drawn from within the receiving cavity to the outside of the housing.

4. The display panel as recited in claim 3, wherein the first control state of the control device is a state in which the control device discharges the moisture drawn from within the receiving cavity; and wherein the second control state of the control device is a state in which the control device draws the moisture from within the receiving cavity.

5. The display panel as recited in claim 2, wherein the air outlet comprises a first air outlet and a second air outlet, which are disposed on opposite sides of the housing, respectively;
wherein the first airflow channel comprises a main air cavity, a first branch airway, and a second branch airway; wherein the first branch airway and the first air outlet are arranged on the same side, and wherein the second branch airway and the second air outlet are arranged on the same side;
wherein one side of the main air cavity facing away from the receiving cavity communicates with the air inlet; and wherein the side of the main air cavity facing towards the receiving cavity communicates with each of the first branch airway and the second branch airway;
wherein one end of the first branch airway facing away from the main air cavity communicates with the first air outlet; and wherein one end of the second branch airway facing away from the main air cavity communicates with the second air outlet.

6. The display panel as recited in claim 5, wherein the power device is disposed inside the main air cavity and divides the main air cavity into a first air duct and a second air duct, wherein the airflow inside the main air cavity is operative to drive the power device to switch between a first state and a second state.

7. The display panel as recited in claim 6, wherein when the power device is in the first state, the first air duct communicates with the first branch airway and the second branch airway, and wherein an air pressure in the first branch airway is operative to control the control device to be in the first control state;
or when the power device is in the first state, the second air duct communicates with the first branch airway and the second branch airway, and the air pressure in the second branch airway is operative to control the control device to be in the first control state.

8. The display panel as recited in claim 7, wherein when the power device is in the second state, the first air duct, the second air duct, the first branch airway, and the second branch airway are all in communication with each other, and wherein the control device is in the second control state.

9. The display panel as recited in claim 8, wherein the power device comprises a fixing piece and a rotatable piece, wherein the fixing piece is connected to the inner wall of the main air cavity, wherein the rotatable piece is connected to the fixing piece via a rotating shaft, wherein the rotatable piece is operative to swing between the first air duct and the second air duct along the main air cavity;
wherein one side of the rotatable piece facing towards the first air duct, and another side of the rotatable piece facing towards the second air duct each have an arcuate shape, and wherein the rotatable piece has Coandă effect.

10. The display panel as recited in claim 9, wherein the housing further comprises a first cavity and a second cavity that are disposed adjacent to each other, wherein the second cavity is disposed adjacent to the receiving cavity, wherein the first cavity is disposed on a side of the second cavity facing from the receiving cavity;
wherein the control device comprises a first control assembly and a switch assembly, wherein the first control assembly is disposed in the first cavity, and wherein the switch assembly is disposed in the second cavity; wherein the first cavity is connected to the exhaust outlet through the second airflow channel;
wherein there is disposed an air suction tube in the second cavity, wherein one end of the air suction tube communicates with the first cavity, and wherein another end of the air suction tube communicates with the receiving cavity.

11. The display panel as recited in claim 10, wherein when the control device is in the first control state, the first control assembly is configured to control the second airflow channel to be opened thus communicating the exhaust outlet with the first cavity, and wherein the switch assembly is configured to control the air suction tube to be closed thus disconnecting the receiving cavity from the first cavity;
wherein when the control device is in the second control state, the first control assembly is configured to control the second airflow channel to be closed thus disconnecting the exhaust outlet from the first cavity, and wherein the switch assembly is configured to control the air suction tube to be opened thus communicating the receiving cavity with the first cavity.

12. The display panel as recited in claim 11, wherein the first cavity is disposed between the first branch airway and the second branch airway; wherein one end of the first cavity communicates with the first branch airway, and another end of the first cavity communicates with the second branch airway, wherein the first cavity extends in a direction pointing from the first branch airway towards the second branch airway.

13. The display panel as recited in claim 12, wherein the first control assembly comprises a first control structure, a second control structure, and an elastic piece; wherein the first control structure is disposed in the first cavity on a side adjacent to the first branch airway, the second control structure is disposed in the first cavity on a side adjacent to the second branch airway;
wherein the elastic piece is connected between the first control structure and the second control structure; wherein the elastic piece, in its natural state, extends the first control structure and the second control structure to two ends of the first cavity, respectively;
wherein a connection port of the second airflow channel to the first cavity is disposed between the first control structure and the second control structure.

14. The display panel as recited in claim 13, wherein the elastic piece is a spring.

15. The display panel as recited in claim 14, wherein when the first control structure is subjected to an air pressure in the first branch airway, or when the second control structure is subjected to an air pressure in the second branch airway, the control device is in the first control state;
wherein when neither the first control structure nor the second control structure is subjected to an air pressure, the control device is in the second control state.

16. The display panel as recited in claim 15, wherein the first control structure comprises a first support piece, a first support rod, and a first limiting member; wherein the first support rod is connected between the first support piece and the first limiting member, extending the first limiting member into the first cavity;
wherein the second control structure comprises a second support piece, a second support rod, and a second limiting member; wherein the second support rod is connected between the second support piece and the second limiting member, extending the second limiting member into the first cavity;
wherein there is further disclosed on an inner wall of the first cavity a first limiting piece and a second limiting piece, wherein the first limiting piece is disposed between the first support piece and the first limiting member, and wherein the second limiting piece is disposed between the second support piece and the second limiting member;
wherein when the elastic piece is in its natural state, one side of the first limiting member adjacent to the first support piece abuts against the first limiting piece, and wherein one side of the second limiting member adjacent to the second support piece abuts against the second limiting piece.

17. The display panel as recited in claim 10, wherein the switch assembly comprises a first assembly and a second assembly, wherein the first assembly and the second assembly are respectively disposed on opposite sides along a direction of extension of the air suction tube; wherein the air suction tube is made of an elastic deformation material;
wherein the first assembly comprises a first pipeline and a first pressing assembly, wherein one end of the first pipeline communicates with the first cavity, and wherein another end of the first pipeline is connected to an inner wall of the second cavity facing away from the first cavity; wherein the first pressing assembly comprises a first connection piece and a first pressing piece, wherein the first connection piece is disposed inside the first pipeline, wherein the first pressing piece is connected to a side of the first connection piece facing towards the air suction tube;
wherein the first pipeline further comprises a first control member configured to control the first pressing piece to press or release the air suction tube;
wherein the second assembly comprises a second pipeline and a second pressing assembly, wherein one end of the second pipeline is connected to the first cavity, and wherein another end of the second pipeline is connected to the inner wall of the second cavity facing away from the first cavity; wherein the second pressing assembly comprises a second connection piece and a second pressing piece, wherein the second connection piece is disposed inside the second pipeline, wherein the second pressing piece is connected to a side of the second connection piece facing towards the air suction tube; wherein the second pipeline further comprises a second control member configured to control the second pressing piece to press or release the air suction tube;
wherein when the control device is in the first control state, the first control member and the second control member are configured to respectively control the first pressing piece and the second pressing piece to compress the air suction tube thereby closing the air suction tube at a pressed portion;
wherein when the control device is in the second control state, the first control member and the second control member are configured to respectively control the first pressing piece and the second pressing piece to release the air suction tube.

18. The display panel as recited in claim 10, wherein the housing further comprises a third cavity that is disposed on a side of the second airflow channel adjacent to the exhaust outlet and that communicates with the second airflow channel;
wherein the control device further comprises a second control assembly disposed inside the third cavity and configured to control communication or disconnection between the second airflow channel and the exhaust outlet;
wherein when the control device is in the first control state, the first control assembly is configured to control the second control assembly to communicate the second airflow channel with the exhaust outlet;
wherein when the control device is in the second control state, the first control assembly is configured to control the second control assembly to disconnect the second airflow channel from the exhaust outlet.

19. A display device, comprising a rear shell and a display panel, wherein the rear shell is configured to enclose the display panel; wherein the display panel comprises an encapsulation body and a plurality of pixel modules disposed inside the encapsulation body; wherein each of the plurality of pixel modules is configured for individual display, and wherein there is disposed a receiving cavity at an edge of the encapsulation body;
wherein the display panel further comprises a moisture processing structure, which is partially disposed inside the receiving cavity, and there is defined a gap between the moisture processing structure and the plurality of pixel modules;
wherein the moisture processing structure comprises a housing, a power device, and a control device; wherein one part of the housing is connected to the encapsulation body, and wherein another part of the housing is exposed outside the encapsulation body; wherein both the power device and the control device are disposed within the housing, wherein the control device is disposed in the housing on a side adjacent to the receiving cavity, and wherein the power device is disposed in the housing on a side facing away from the receiving cavity;
wherein the power device is configured to supply power to the control device to control the control device to discharge moisture from within the receiving cavity to an outside of the housing.
